(19) United States
(12) Patent Application Publication
(10) Pub. No.: US 2026/0304715 A1
(43) Pub. Date: Oct. 1, 2026

(54) ELECTRONIC CONTROL UNIT

(71) Applicant: Kubota Corporation, Osaka (JP)

(72) Inventors: David Joseph Kelly, Mesa, AZ (US); Jonathan Louis Baker, Chandler, AZ (US)

(73) Assignee: Kubota Corporation, Osaka (JP)

(21) Appl. No.: 19/095,798

(22) Filed: Mar. 31, 2025

(51) Int. Cl. H05K 7/20; H05K 1/02; H05K 7/14

(52) U.S. Cl. CPC H05K 7/209; H05K 1/0237; H05K 1/0296; H05K 7/14322; H05K 7/14327

(57) ABSTRACT

An electronic control unit includes a housing including a body formed from a thermally conductive material, first and second printed circuit board assemblies disposed within the housing, and a passive thermal control system. The passive thermal control system includes a first thermal interface material positioned between the first and second printed circuit board assemblies, a second thermal interface material positioned between a heat-generating part of the second printed circuit board assembly and a first portion of an interior surface of the body, and a third thermal interface material positioned between, and in contact with each of, the first printed circuit board assembly and a second different portion of the body. The first thermal interface material, the second thermal interface material, and the heat-generating part are axially aligned with one another and each has substantially the same footprint.

### TECHNICAL FIELD

This disclosure relates to an electronic control unit and, in particular, to an electronic control unit having a thermal control system for use in a vehicle or other machine including a transportation system to operate in off-highway environments (e.g., off-road environments).

### BACKGROUND

An electronic control unit may be mounted on a vehicle and used to control an operation of the vehicle. The electronic control unit generally includes a processor that implements a control function of the vehicle (e.g., via sensors and/or actuators associated with the vehicle) by executing software stored in non-volatile memory. When an electronic control unit is utilized on off-highway vehicle, such as an agricultural vehicle, the electronic control unit may be subjected to harsh environmental conditions (e.g., extreme temperatures, dust, dirt, etc.).

### SUMMARY

This disclosure is directed to an electronic control unit having a thermal control system for dissipating heat generated within the electronic control unit. Thermal control components are integrated into and/or attached to the electronic control unit to transfer and spread heat generating from the electronic control unit to the outside environment such that a suitable or desired thermal profile of the electronic control unit is maintained.

In aspects, the thermal environment of the electronic control unit may be managed passively through structural and electrical design considerations including, for example, material selection, component location and orientation, thermal interfaces, and circuit board layout. The electronic control unit of this disclosure may have a passive thermal control system that may be configured to operate under a wide range of temperatures. In some aspects, the electronic control unit may be configured to operate within an ambient temperature range of about −40° C. to about 85° C. The passive thermal control system maintains a desired thermal profile of the electronic control unit by, for example, conducting, spreading, and transferring the internal heat load of the electronic control unit to the housing of the electronic control unit and, in turn, to the outside environment (e.g., a frame of the vehicle to which the electronic control unit may be attached).

In aspects, such as in environments having extreme ambient temperatures (e.g., conditions in which the ambient temperature may be outside an operating temperature range of the electronic control unit), an active thermal control system may be provided as a removable add-on module to the electronic control unit, or an active thermal control system may be integrated into the electronic control unit. Accordingly, a same model of electronic control unit may be operated without the removable add-on in environmental conditions within a threshold (e.g., a threshold ambient temperature), or with the removable add-on in harsh environmental conditions (e.g., not within the threshold).

In aspects, the electronic control unit of this disclosure may be particularly suited for use in off-road vehicles and equipment, such as vehicles or other machines including a transportation system and/or at least one implement (e.g., agricultural and construction vehicles, machines, implements, and attachments, as well as other ruggedized machines that may be intended to operate (e.g., work in) harsh environmental conditions (e.g., susceptible to airborne particles and debris). For example, the electronic control unit of this disclosure does not include cooling fans or fine finned heat sinks that can clog from dust and lower the operating efficiency of the electronic control unit, nor does the electronic control unit circulate coolant or contain liquid thereby lowering maintenance needs and costs and preventing the risk of leaks. While the electronic control unit are described as being particularly suited for off-road applications, it should be understood that the electronic control unit may be used in any vehicle (passenger or autonomous), machine, or part thereof utilizing an electronic control unit.

In accordance with aspects of this disclosure, an electronic control unit includes a housing, a first printed circuit board assembly, a second printed circuit board assembly, and a passive thermal control system. The housing includes a body and a cover. The body is formed from a thermally conductive material and defines a cavity. The first and second printed circuit board assemblies are disposed within the cavity of the body. The passive thermal control system includes a first thermal interface material positioned between the first printed circuit board assembly and the second printed circuit board assembly, a second thermal interface material positioned between a heat-generating part of the second printed circuit board assembly and a first portion of an interior surface of the body, and a third thermal interface material positioned between, and in contact with each of, the first printed circuit board assembly and a second different portion of the body. The first thermal interface material, the second thermal interface material, and the heat-generating part are axially aligned with one another and each has a footprint that is substantially the same to one another.

The first printed circuit board assembly may include a printed circuit board having an interior array of vias defined therethrough. The interior array of vias may be axially aligned with the first thermal interface material and may have a footprint that may be substantially the same as the first thermal interface material. In some aspects, a conductive trace is disposed over the interior array of vias and the first thermal interface material contacts the conductive trace.

The body of the housing may include a shelf disposed within the cavity, and the second different portion of the body may be part of the shelf. The first portion of the interior surface of the body may be part of a wall of the body or some other part of the body that is different than the shelf. In some aspects, one or both of the shelf and the second different portion of the body extend(s) around an outer periphery of the cavity. In some aspects, the shelf is monolithically formed with the body of the housing. In some aspects, the third thermal interface material covers the shelf. The first printed circuit board assembly may include a printed circuit board having a peripheral array of vias defined therethrough and extending around a peripheral region of the printed circuit board. The third thermal interface material may be axially aligned with the peripheral array of vias. In certain aspects, the peripheral array of vias has a footprint that is substantially the same as a footprint of the shelf. A conductive trace may be disposed over the peripheral array of vias and the third thermal interface material may contact the conductive trace.

The housing may include a plurality of mounting tabs extending from an outer surface of the body. The plurality of mounting tabs may be formed from a thermally conductive material. In some aspects, the plurality of mounting tabs is longitudinally offset from a bottom wall of the body and an air gap is defined between the bottom wall and the plurality of mounting tabs. In certain aspects, the bottom wall is textured.

The cover may be formed from a non-conductive material configured to allow passage of radio frequency energy therethrough. In some aspects, the electronic control unit further includes an antenna disposed within the housing and electrically coupled to the first printed circuit board assembly or the second printed circuit board assembly. The antenna may be positioned adjacent the cover.

The heat-generating part of the second printed circuit board assembly may be a processor. The second printed circuit board assembly may be a system-on-module.

The electronic control unit may be cooled passively, without fans, in all modes of operation. This is in contrast to some heat dissipation systems that may operate passively at times, but may not be arranged to never operate without a fan installed. In some aspects, the electronic control unit may be for a vehicle or other machine, which may be cooled passively at all time and/or in all modes of operation (in a majority of geographies/conditions in some examples).

In accordance with aspects of this disclosure, an electronic control unit system with modularity for operation in a vehicle or other machine that includes a transportation system, in which the vehicle or other machine is suitable for transportation within, or operation within, a wide range of geographical areas, includes a modular heat transfer system. The modular heat transfer system includes the passive thermal control system of the electronic control unit and an active thermal control system releasably attachable to the electronic control unit and configured to regulate a temperature within the electronic control unit when thermally coupled to the passive thermal control system. The module heat removal system is operable without the active thermal control system attached thereto, in environmental conditions within a first threshold, and with the active thermal control system operably coupled thereto, in environmental conditions with a second threshold, wherein the second threshold is different than (e.g., greater than) the first threshold.

The active thermal control system may include a solid state thermoelectric device to operate in a vehicle (or other machine including a transportation system, such as wheels, tracks, walkers, or the like, or combinations thereof). The vehicle or other machine including the transportation system may include an implement to work an environment (such as a digger, mowing blades, a crop-sprayer, or the like, or combinations thereof). The transportation system may be an off-highway transportation system for moving the vehicle or other machine to and from an off-road environment to perform working tasks using the implement (of course, in some examples the off-highway transportation system may be arranged to operate during the working tasks, also).

Other aspects, features, and advantages will be apparent from the description, drawings, and the claims.

### BRIEF DESCRIPTION OF THE DRAWINGS

Various aspects of this disclosure are described hereinbelow with reference to the drawings, which are incorporated in and constitute a part of this specification, wherein:

FIG. 1 is an isometric view of an electronic control unit in accordance with an aspect of this disclosure;

FIG. 2 is a top view of the electronic control unit of FIG. 1;

FIG. 3 is a bottom view of the electronic control unit of FIG. 1;

FIG. 4 is an end view of the electronic control unit of FIG. 1;

FIG. 5 is a side view of the electronic control unit of FIG. 1;

FIG. 6 is an isometric view of the electronic control unit of FIG. 1, showing a housing assembly in exploded view;

FIG. 7 is a top, isometric view of the body of the electronic control unit of FIG. 1;

FIG. 8 is an isometric view of the electronic control unit of FIG. 1 without a cover assembly, showing a wiring harness assembly in exploded view;

FIG. 9 is an exploded bottom, isometric view of a cover assembly of the electronic control unit of FIG. 1, in which a light pipe of the electronic control unit is separated from a cover;

FIG. 10 is a bottom view of electronics disposed within the electronic control unit of FIG. 1, the electronics includes a first printed circuit board assembly and a second printed circuit board assembly illustrated in transparency;

FIG. 11 is a bottom, isometric view of the electronics of FIG. 10;

FIG. 12 is a cross-sectional view of the electronic control unit of FIG. 1, taken along line 12 -12 of FIG. 1;

FIG. 13 is a cross-sectional view of the electronic control unit of FIG. 1, taken along line 13 -13 of FIG. 1;

FIG. 14 is a schematic, cross-sectional view of the electronic control unit of FIG. 1 attached to an active thermal control system in accordance with an aspect of this disclosure;

FIG. 15 is a schematic, cross-sectional view of an electronic control unit and an active thermal control system in accordance with another aspect of this disclosure;

FIG. 16 is a schematic, cross-sectional view of an electronic control unit and an active thermal control system in accordance with yet another aspect of this disclosure; and

FIG. 17 is a graph showing an internal temperature of the ECU of FIG. 1 over time according to the test performed in Example 1.

### DETAILED DESCRIPTION

Aspects of this disclosure will now be described in detail with reference to the drawing figures wherein like reference numerals identify similar or identical elements. Throughout this description, the terms “generally,” “substantially,” and “about” shall be understood as words of approximation that take into account relatively little to no variation in the modified terms (e.g., differing by less than 5%). Directional reference terms, such as “above,” “below,” “upward,” “downward,” “top,” “bottom” and the like, are used to ease description of the aspects of this disclosure and are not intended to have any limiting effect on the ultimate orientation of a structure or any part thereof. Additionally, it should be understood that various components of this disclosure, such as those numbered in the 100 series or plainly numbered, correspond to components of the disclosure similarly prime numbered, such that redundant explanation of similar or identical components need not be repeated herein and only the differences therebetween are described herein.

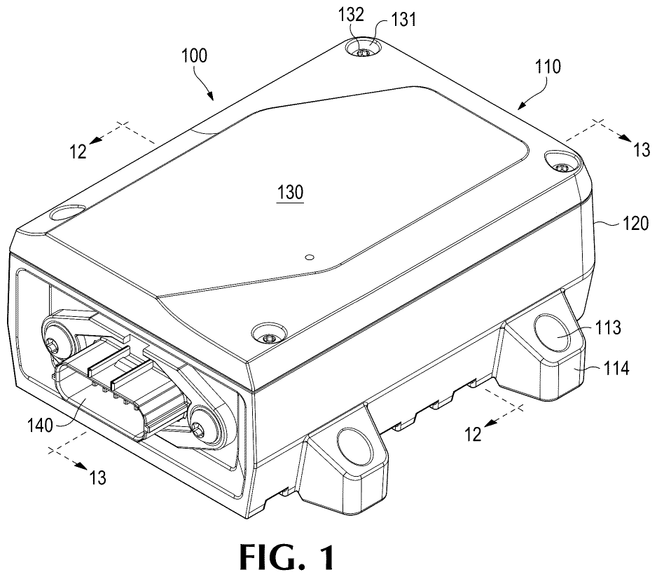

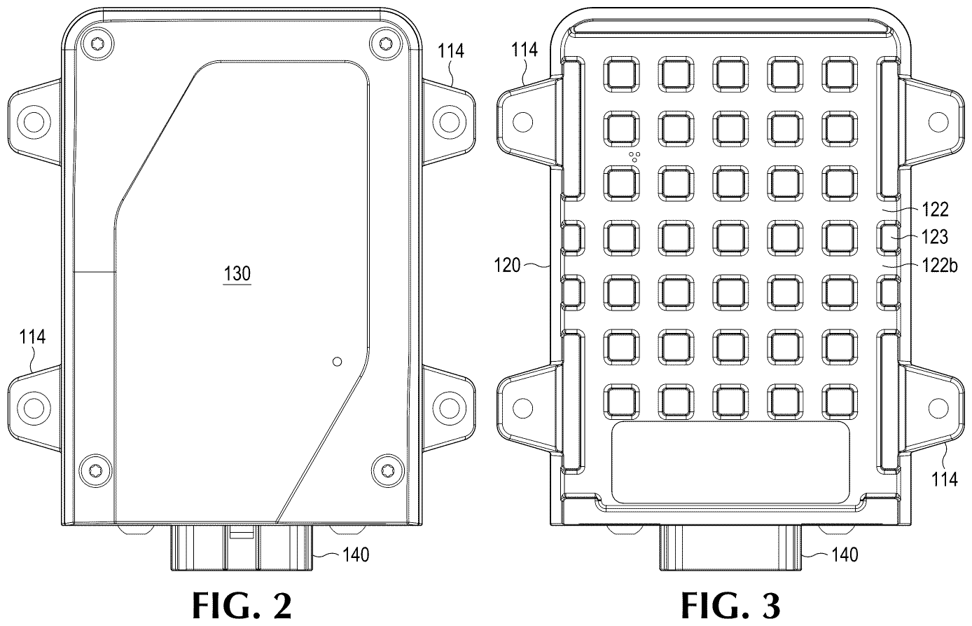

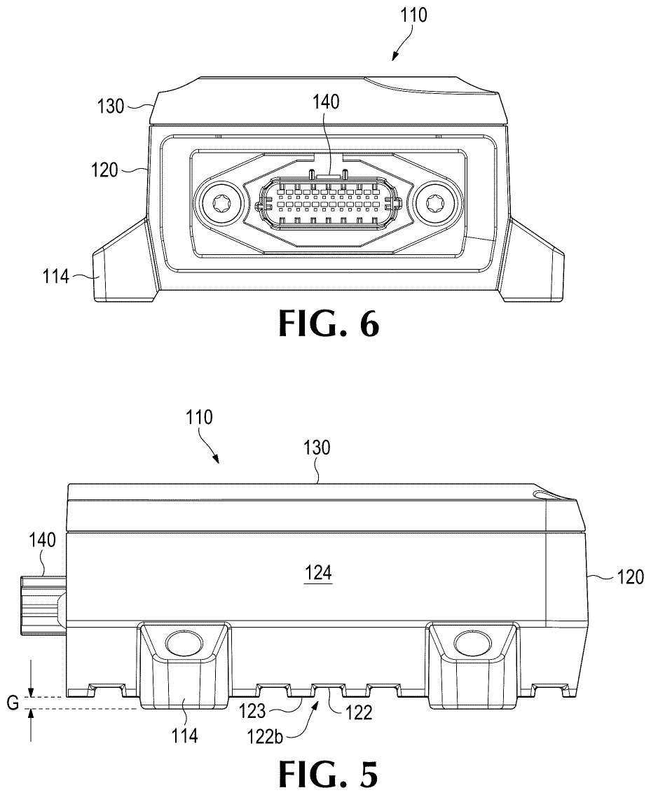

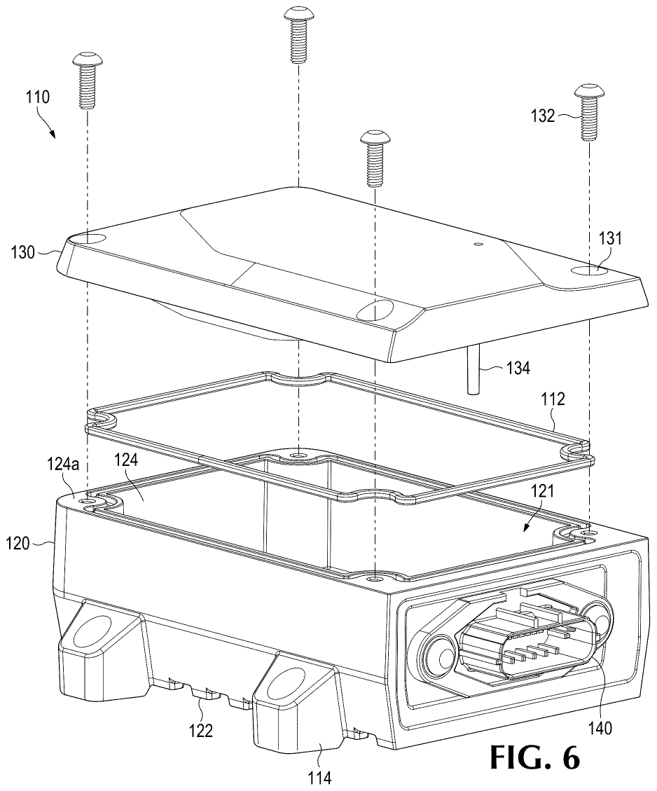

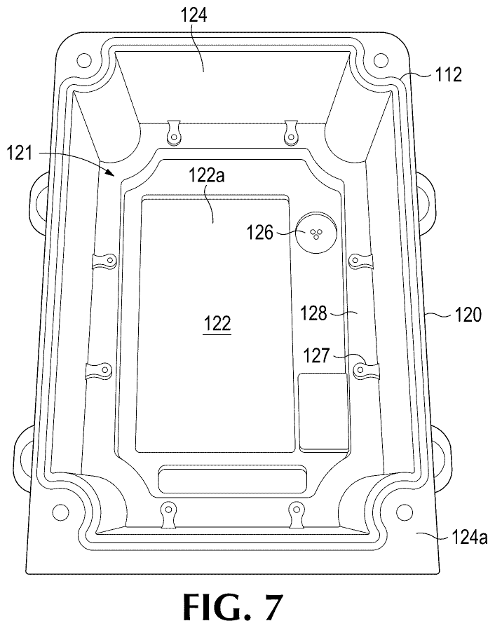

Referring now to FIGS. 1-7, an electronic control unit (ECU) 100 includes a housing 110 including a body 120 and a cover 130. The body 120 includes a cavity 121 defined by a bottom wall 122 and a side wall 124 extending around an entire periphery of the bottom wall 122. The side wall 124 has an open top surface 124a on which the cover 130 is secured to enclose the cavity 121 within the housing 110 of the ECU 100. A gasket 112 is positioned between the body 120 and the cover 130 to mate the cover 130 and the body 120 in a fluid-tight manner. It is envisioned that other materials or methods may be utilized to create a tight seal between the body 120 and the cover 130, such as using sealants (e.g., foams or caulks) and/or sealing methods involving, for example, heat and/or pressure. In some aspects, the cavity 121 may be an environmentally-isolated cavity (to restrict an introduction of contaminants or other selected matter into the ECU).

The bottom wall 122 includes a cavity-facing surface 122a and an outward-facing surface 122b opposite the cavity-facing surface 122a. A vent 126 is defined through the bottom wall 122 and is configured to allow airflow into and out of the cavity 121, for example, for pressure equalization between the interior and exterior of the housing 110 while minimizing or preventing the introduction of liquids (e.g., water) and/or particulates (e.g., dust). In aspects, the vent 126 is sized and shaped as a pocket having a membrane or filter (not explicitly shown) disposed therein. It should be understood that the vent 126 may be positioned in other locations, such as through the side wall 124 of the body 120 or through the cover 130. In this embodiment, airflow into and out of the body 120 are on a same side of the body 120.

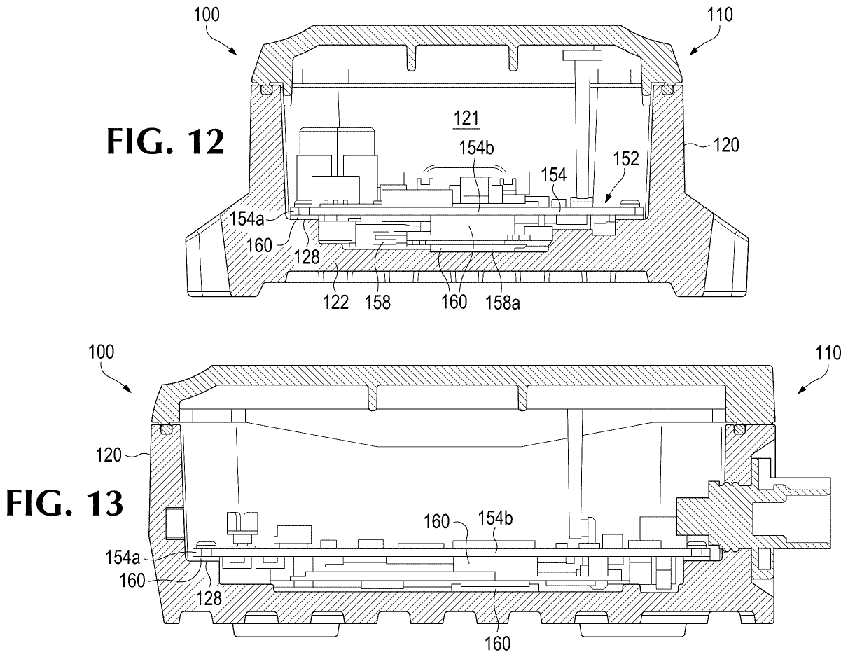

A ledge or shelf 128 extends from the body 120 into and around an outer periphery of the cavity 121 defined within the body 120. In some aspects, the shelf 128 is integrally or monolithically formed with the body 120. While the shelf 128 is shown as a continuous structure, it should be understood that the shelf 128 may be discontinuous and include breaks or openings depending upon, for example, the layout of the components within the cavity 121. The shelf 128 may include one or more mounting bosses 127 or other mating connectors for joining and securing a component (e.g., an electronic device) disposed within the cavity 121 to the base 120. The mounting bosses 127 may be raised relative to the shelf 128 to accommodate placement of thermal interface material 160 (FIG. 12) on the shelf 128.

The outward-facing surface 122b of the bottom wall 122 may be textured and include protrusions 123 (e.g., heat transfer extensions) to increase the surface area of the outward-facing surface 122b exposed to the outside ambient air for increased heat dissipation. In aspects, the ECU 100 is configured for use in harsh environments, e.g., off-road applications, and thus, the protrusions 123 are broad (e.g., having a coarse pitch) and include wide gaps between the protrusions 123 as compared to some other heat transfer extensions such as heat transfer fins to minimize the occurrence of clogging from debris, dirt, dust, or other contaminants in the environment. Accordingly, the size, shape, and spacing of the protrusions 123 are within the purview of those skilled in the art and dependent upon, for example, the environmental conditions in which the ECU 100 is to be used.

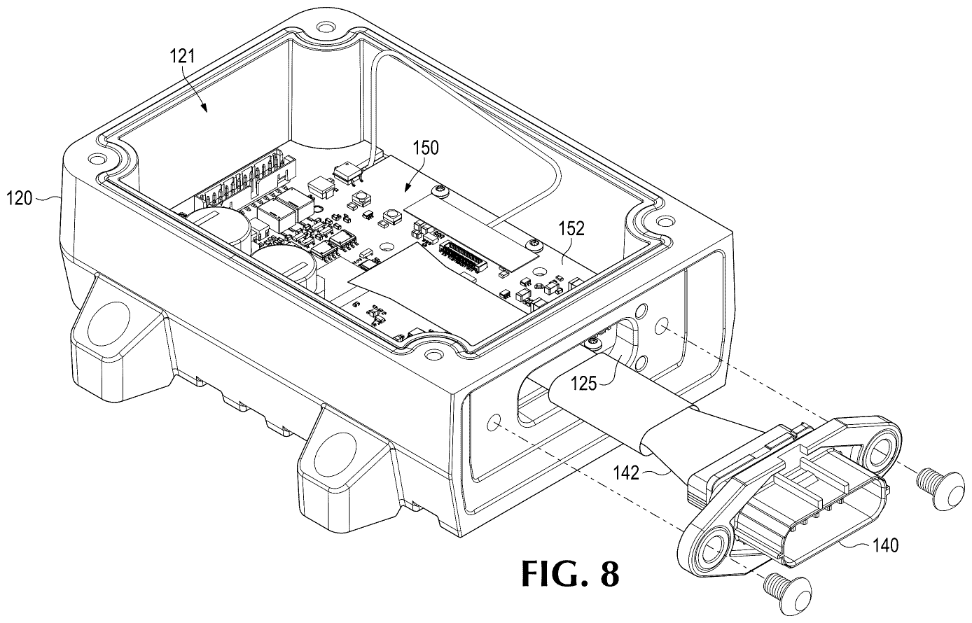

The side wall 124 includes or more openings 125 (e.g., connector openings) defined therethrough that are each configured and dimensioned to receive and sealingly engage a connector 140 (e.g., an electrical connector). The connector 140 is electrically coupled to electronics 150 disposed within the cavity 121. For example, as shown in FIG. 8, the connector 140 is connected to a wiring harness 142 that is electrically coupled to a first printed circuit board assembly 152 disposed within the cavity 121 of the body 120 to transmit electrical power and signals between the ECU 100 and other electronic devices (e.g., a mechanical drive unit configured for precision autosteering). In other aspects, the connector 140 may be directly connected to the electronic 150 without a wiring harness.

The body 120 (including, for example, the shelf 128) is formed from one or more thermally conductive materials (e.g., a thermally conductive metal, or some other thermally conductive material). In aspects, the body 120 is made from aluminum, however, it is envisioned that the body 120, or components thereof, may be formed from other thermally conductive materials, such as, copper, silver, gold, zinc, and/or alloys thereof, among other materials within the purview of those skilled in the art that effectively transfer heat. In some examples, the shelf 128 may be formed from a material having a different thermal conductivity than a portion of the body, such as the bottom wall 122 of the body 120.

With reference again to FIGS. 1-6, the housing 110 includes a plurality of mounting tabs or feet 114 extending from the body 120. In some aspects, the plurality of mounting tabs 114 are integrally or monolithically formed with the body 120 and thus, are formed from thermally conductive material(s). The plurality of mounting tabs 114 are configured for securing the ECU 100 to a target surface (e.g., a vehicle frame or other desired surface). In aspects, the plurality of mounting tabs 114 includes through-holes 113 dimensioned to receive a fastener (not shown) for securing the ECU 100 to the target surface. It should be understood that any of a variety of connectors may be utilized to secure the ECU 100 to the target surface. The plurality of mounting tabs 114 extend outwardly from the body 120 and downwardly beyond the bottom wall 122. Accordingly, the plurality of mounting tabs 114 are longitudinally offset from the outward-facing surface 122b of the bottom wall 122 and defines an air gap “G” between the bottom wall 122 and the plurality of mounting tabs 114 such that when the ECU 100 is mounted to the target surface, thermal dissipation is provided through the plurality of mounting tabs 114.

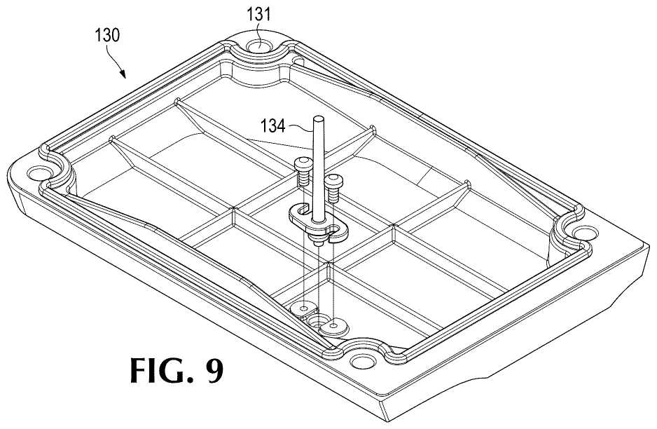

With continued reference to FIGS. 1-6, in conjunction with FIG. 9, the cover 130 may be formed from a different material than the body 120 (e.g., from a non-metal such as one or more polymers or composites thereof). In aspects, the cover 130 is formed from polymers that allow radio frequency energy to pass therethrough such as, for example, polycarbonate, polytetrafluoroethylene, poly(methyl methacrylate), polyoxymethylene, or acrylonitrile butadiene styrene. The cover 130 may include a plurality of through-holes 131 dimensioned to receive screws 132 for releasably securing the cover 130 to the body 120. It is envisioned that any of a variety of connectors or connection methods may be utilized to secure the cover 130 to the body 120. In some aspects, a light pipe 134 is inserted into and secured to the cover 130 for display of a status or power indicator (e.g. an LED) of the ECU 100.

The ECU 100 includes electronics 150 disposed within the cavity 121. The electronics 150 includes, for example, one or more controllers (microcontrollers), sensors, actuators, memories, processors (microprocessors), power supplies, and communication interfaces. The electronics also includes software (e.g., code, instructions, programs) stored on non-transitory storage medium (e.g., a memory) that is executed by processing unit(s) (e.g., processors, cores) to carry out the desired functions and operations of the ECU 100.

Some systems using passive heat dissipation provide both an intake vent and an exhaust vent, such as on opposite sides of an enclosure. Such an arrangement may improve heat dissipation by supporting the chimney effect (especially when the intake is near a bottom of the enclosure and the exhaust vent is near a top of the enclosure), which may increase the draw from the intake vent thereby improving passive heat dissipation. In an off-road environment and/or in a working environment, particulates (e.g., dust) may be in abundance, and the passive draw (from the chimney effect) may be capable of pulling dust into the enclosure. Referring again to FIG. 3, the protrusions 123 are external to the body 120, so any movement of air driven may heat dissipating from them may be outside the enclosure. As such, there is a very low likelihood of dust entering the vent 126. It may be possible to isolate the vent 126 from a working zone around some or all of the vehicle or other working machine (so that any air entering the vent 126 is cleaner and/or cooler). In embodiments that utilize a vent (e.g., a single vent 126), it may be possible to cover the vent 126 with a filter (without overheating, since protrusions 123 produce heat dissipation primarily using outside air).

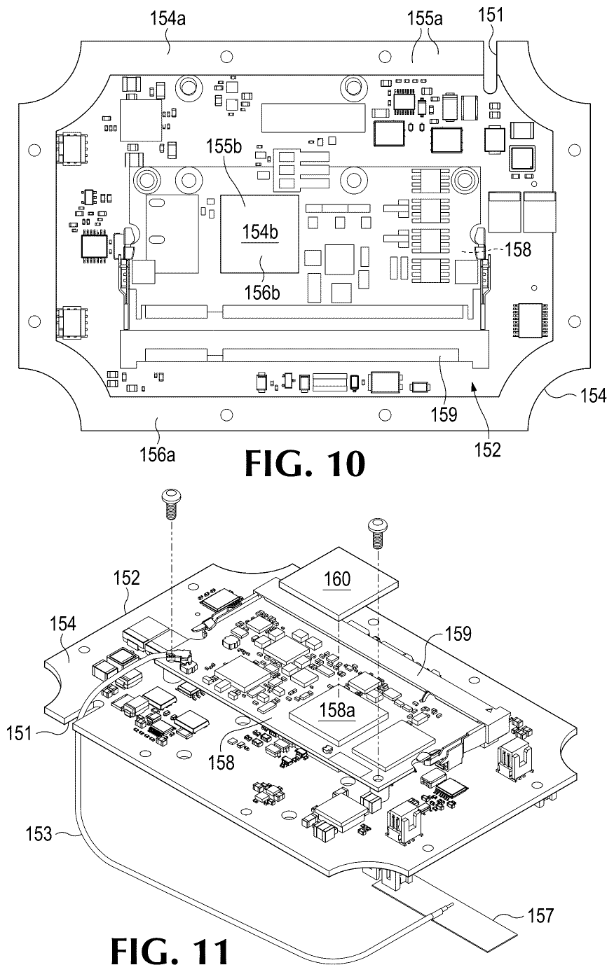

FIGS. 10 and 11 show a first printed circuit board assembly 152 and a second printed circuit board assembly 158 connected to the first printed circuit board assembly 152 via a connector 159. In aspects, the second printed circuit board assembly 158 is a system-on-module including at least one processor 158a. In aspects, such as use of the ECU in an autosteering system, the processor 158a may be a multi-core processor (e.g., a five-core processor) running multiple operating systems and supporting multiple communications protocols with communication controllers. In such aspects, the second printed circuit board assembly 158 further includes radio technology, such as WiFi and Bluetooth concurrent operation radios.

The first printed circuit board assembly 152 includes a printed circuit board 154 having a plurality of electronic devices and components associated therewith (e.g., soldered) including, for example, integrated circuits and sensors, among various electronic components within the purview of those skilled in the art (e.g., resistors, capacitors, diodes, transistors, inductors, LEDs, switches, etc.). The printed circuit board 154 may be double-sided and include different electronic devices and components mounted to, or otherwise associated with, the opposing sides of the printed circuit board 154. In aspects, such as use of the ECU in an autosteering system, the first printed circuit board assembly 152 includes power conversion device(s), fault detecting circuits, safety analysis processors, communications support, memory systems, a motion and location positioning unit, in addition to other supporting devices and components.

The printed circuit board 154 is multi-layered and includes a plurality of ground planes (e.g., copper ground planes) connected to a peripheral array of vias 155a and an interior array of vias 155b disposed, respectively, within a peripheral region 154a and an interior region 154b of the printed circuit board 154. The peripheral region 154a and the interior region 154b are both exclusion zones (e.g., component free regions) of the printed circuit board 154. The peripheral region 154a of the printed circuit board 154 includes a conductive trace 156a in the form of a gold-plated copper ring disposed on an outer surface of the peripheral region 154a, and the interior region 154b includes a conductive trace 156b in the form of a gold-plated copper plate disposed on an outer surface of the interior region 154b. The conductive traces 156a, 156b are both disposed on the same side of the printed circuit board 154 that faces the second printed circuit board assembly 158. In some aspects, a cutout 151 extends through a portion of the peripheral region 154a to accommodate passage of wires or cables, such as a wire 153 coupling an antenna 157 to the second printed circuit board assembly 158.

In some embodiments, one or more characteristics (e.g., dimensions and/or material selection) of a portion of the body 120 may be optimized to maximize heat transfer from one of the thermal interface materials (e.g., thermal interface material 160) to outside air (via the protrusions 123 of FIG. 1). For instance, a corresponding portion of the bottom wall may be thinner than another portion of a wall of the body 120, which may locate an outer feature of the body 120 (e.g., the outward-facing surface 122b) as close as possible to a heat generating part. For example, a portion of the bottom wall 122 associated with the thermal interface material 160 may be thinner than, say, a side wall of the body 120, as illustrated. In another example, the corresponding portion of the bottom wall may be formed from a material that has a greater thermal conductivity than another portion of the body 120. The optimization of the one or more characteristics of the corresponding portion of the bottom wall may increase the rate that heat generated by one of the heat generating parts (e.g., a part of the second printed circuit board assembly 158 is dissipated into outside air by the protrusions 123 (FIG. 1).

With reference now to FIGS. 12 and 13, in conjunction with FIGS. 10 and 11, the footprint (e.g., size and shape) of the peripheral region 154a of the printed circuit board 154 is substantially the same as the footprint of the shelf 128 of the body 120 such that when the first printed circuit board assembly 152 is positioned within the housing 110, the peripheral region 154a and the shelf 128 are axially aligned and overlap one another. The footprint of the interior region 154b of the printed circuit board 154 is substantially the same as the footprint of the processor 158a (or other heat-generating part) of the second printed circuit board assembly 158 such that when the first printed circuit board assembly 152 and the second printed circuit board assembly 158 are coupled together, the interior region 154b and the processor 158a are axially aligned and overlap one another. Further, the conductive traces 156a, 156b also have substantially the same footprint as the peripheral and interior regions 154a, 154b, respectively, and face the shelf 128 and the processor 158a.

Thermal interface materials 160 are utilized to fill spaces between surfaces through which heat transfer is desired. The thermal interface material 160 can be, for example, thermal pads, tapes, greases, gels, foams, adhesives, pastes, etc. within the purview of those skilled in the art known to have high thermal conductivity. The thermal interface material 160 may be the same or different across the ECU 100 and/or combinations of thermal interface materials 160 may be utilized between components.

When the electronics 150 are installed within the housing 110 of the ECU 100, the thermal interface material 160 is disposed between, and in contact (e.g., full contact) with both, the peripheral region 154a of the printed circuit board 154 and the shelf 128 of the body 120, as well as the interior region 154b of the printed circuit board 154 and the processor 158a of the second printed circuit board assembly 158, and the second printed circuit board assembly 158 and the bottom wall 122 of the body 120 to enhance thermal coupling.

In aspects in which the second printed circuit board assembly 158 includes more than one processor or other heat-generating devices, components, or parts, additional exclusion zones may be provided on the printed circuit board 154 and additional thermal interface materials 160 may be utilized similar to the arrangement discussed above with regard to the processor 158a. Further, it is envisioned that other devices and/or components that contribute to the heat load of the ECU 100 may be provided with a similar thermal pathway between the first printed circuit board assembly 152 and/or the second printed circuit board assembly 158, and the body 120 of the housing 110.

Accordingly, the ECU 100 utilizes passive thermal control to move heat generated within the ECU 100 to the housing 110 and out into the external environment without using fans, blowers, liquids, or heat exchangers. In aspects, the temperature rise above ambient temperature within the ECU 100 when the electronic devices 150 are active (e.g., generating up to about 10 W of heat) is about or less than 10° C. and, in some aspects, the temperature rise is about or less than 8° C. and, in certain aspects, the temperature rise is about or less than 6° C., and in certain other aspects, the temperature rise is about or less than 4° C.

In environments susceptible to extreme ambient temperatures (e.g., temperatures below about −40° C. or above about 85° C.), an active thermal control system may be utilized with the ECU 100.

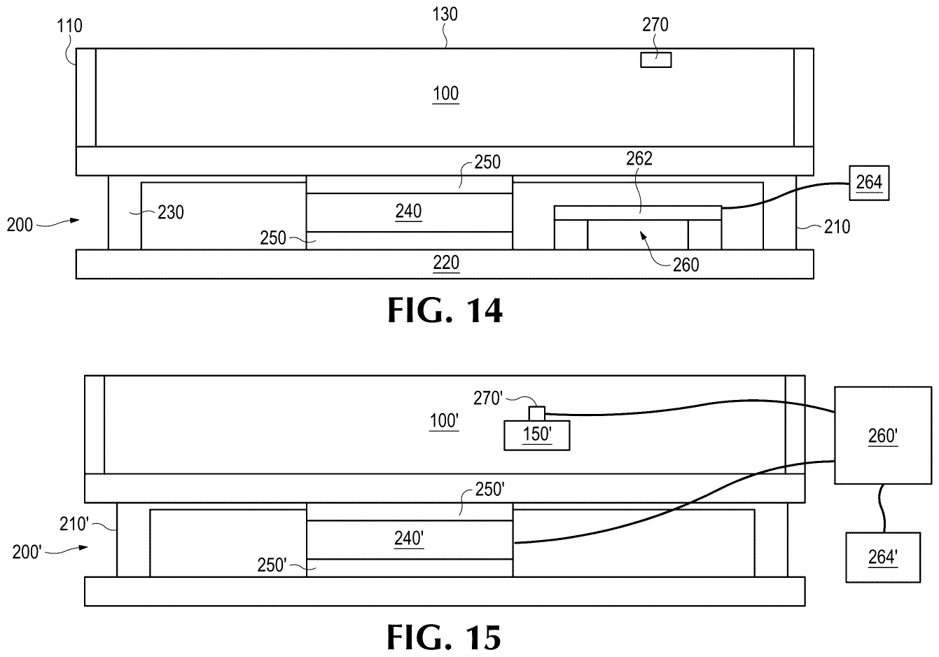

FIG. 14 shows an active thermal control system 200 connected to the ECU 100 as an add-on module or unit. The active thermal control system 200 includes an enclosure 210 having a heat sink 220 configured for positioning against or adjacent to a vehicle frame or other mounting surface, and a shell 230 extending from the heat sink 220 that is configured to be removably attached to the housing 110 of the ECU 100. The heat sink 220 is formed from a thermally conductive material, or combination of materials, and the shell 230 is formed from non-conductive material(s) to, for example, ensure efficient heat flow through an intended thermal pathway including an active thermal device 240. The active thermal device 240 may be a solid state thermoelectric device, such as a peltier device or heat pump configured to transfer heat from one side of the device to the other to either cool or heat the ECU 100. Accordingly, the active thermal device 240 is coupled between the housing 110 of the ECU 100 and the heat sink 220. A thermal interface material 250 may be disposed between, and in contact with, the active thermal device 240 and each of the housing 110 and the heat sink 240. In some aspects, the active thermal device 240 and the thermal interface materials 250 are axially aligned with a heat-generating component of the ECU 100, such as the processor 158a (FIG. 12).

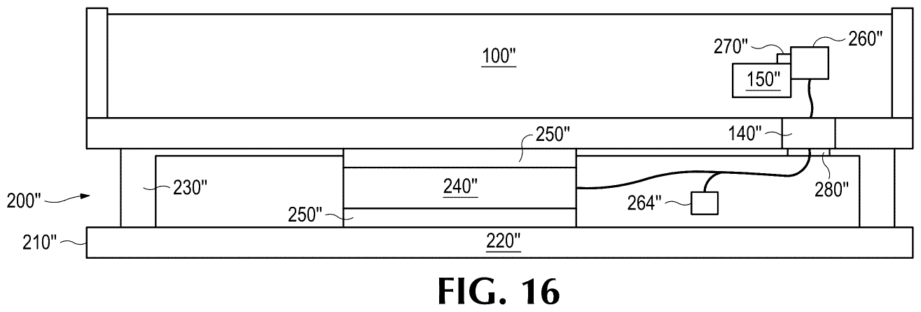

The active thermal control system 200 further includes a temperature controller 260 and a temperature sensor 270. The temperature controller 260 includes a temperature control circuit board assembly 262 mounted within the enclosure 210 of the active thermal control system 200. In some aspects, as shown in FIG. 15, the temperature controller 260′ may be remote, e.g., wiredly or wirelessly connected, to the active thermal device 240′ and, in other aspects, the temperature controller 260″ may be incorporated into the electronics 150″ of the ECU 100″, as shown in FIG. 16. The temperature sensor 270 is applied to the ECU 100 (e.g., within the cover 130) for monitoring and controlling activation of the temperature controller 260 via wired or wireless communication, as seen in FIG. 14. In some aspects, the temperature sensor 270′, 270″ may be incorporated into the electronics 150′, 150″ of the ECU 100′, 100″, as shown in FIGS. 15 and 16, respectively. The temperature controller 260, 260′, 260″ further includes an integrated or remote power source 264, 264′, 264″ so that the active thermal control system 200, 200′, 200″ operates independently from the ECU 100, 100′, 100″. Independent control, for example, allows the active thermal control system 200, 200′, 200″ to be activated by external means, such as a door or seat switch, or other operator presence detection system before the ECU 100, 100′, 100″ is activated, allowing time for the ECU 100, 100′, 100″ to be driven to within its target temperature range and activate with minimal start-up delay. Further, as seen in FIG. 16, the ECU 100″ and the active thermal control system 200″ may include complementary connectors 140″, 280″ for electrically connecting the units together.

It is further envisioned that the active thermal control system may be integrated into the ECU (e.g., into the housing of the ECU).

In a method of use, the active thermal control system 200, 200′, 200″ regulates the temperature within the ECU 100, 100′, 100″ based upon input received by the temperature controller 260, 260′, 260″ from the temperature sensor 270, 270′, 270″. Accordingly, if the sensed temperature is outside a target temperature range (e.g., during start-up or operation), the active thermal device 240, 240′, 240″ activates until the sensed temperature is within the target temperature range.

### Example 1

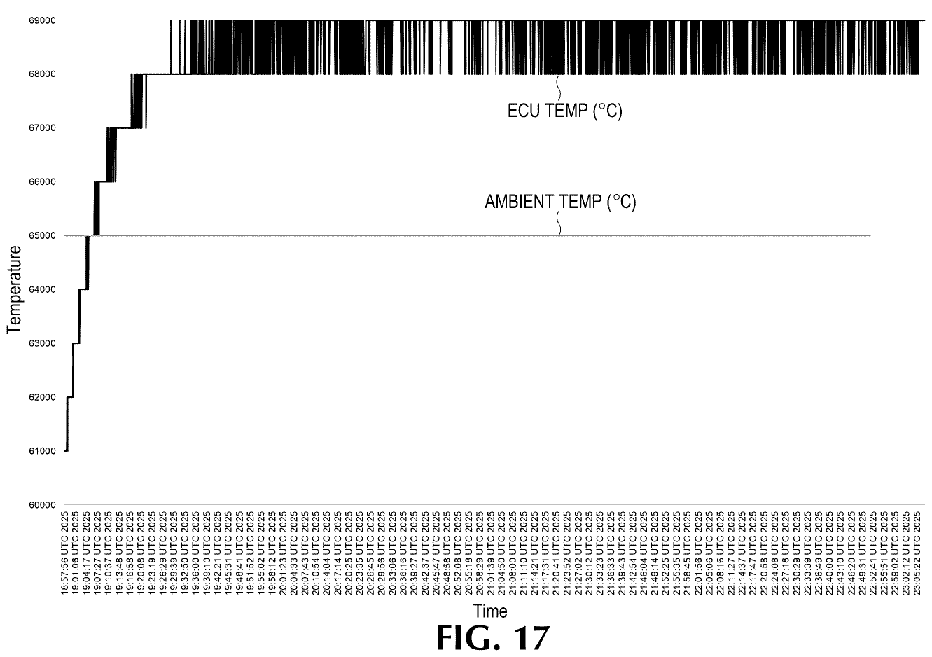

The ECU 100 (FIG. 1) was placed in a calibrated thermal chamber that created a uniform temperature environment, or ambient temperature, of 65° C. The ECU 100 was powered on to its normal operating mode (i.e., the ECU is configured for use as the electronic control unit for an autosteering system that further includes a mechanical drive unit for controlling a steering wheel of a vehicle) over a 4-hour testing window. The ECU 100 generated between about 7.68 W to about 9.99 W of power over the 4-hour run. The temperature within the cavity 121 (FIG. 12) of the ECU 100 was recorded at 5 second intervals over the 4 hours. A temperature rise within the ECU 100 of no greater than about 4° C. above the ambient temperature of 65° C. was recorded over the 4-hour testing window, as shown in FIG. 17. Specifically, 2993 data points are shown in FIG. 17 resulting in a data collection window of 4.15 hours.

### Example 2

The ECU 100 (FIG. 1) was continuously operated under the same testing conditions as Example 1 (i.e., in the calibrated thermal chamber and powered on to its normal operating mode), except that the ambient temperature was set to 75° C. and the testing window was 120 hours. The ECU 100 generated between about 7.68 W to about 9.99 W of power over the 120 hours. A pass/fail status was recorded every second over the 120 hours, the passing criteria including normal device operation (i.e., no detected temperature faults), as well as the recorded temperature within the cavity 121 (FIG. 12) of the ECU 100, as well as the temperature of critical temperature components (e.g., the processor 158a (FIG. 12)) of the ECU, not exceeding the ambient temperature by +10° C. The ECU 100 achieved a consistent passing status over the entire 120-hour run.

While aspects of the disclosure have been shown in the drawings, it is not intended that the disclosure be limited thereto, as it is intended that the disclosure be as broad in scope as the art will allow and that the specification be read likewise. It is to be understood, therefore, that this disclosure is not limited to the precise aspects described, and that various other changes and modifications may be affected by one skilled in the art without departing from the scope or spirit of the disclosure. For example, while various aspects of this disclosure are discussed herein with respect to exemplary electronic control units for use in autosteering systems, it should be understood that electronic control units of this disclosure may be used to control other functions as is within the purview of those skilled in the art. Additionally, the elements and features shown and described in connection with certain aspects of the disclosure may be combined with the elements and features shown and described in connection with certain other aspects of the disclosure without departing from the scope of this disclosure, and that such modifications and variation are also included within the scope of this disclosure. Therefore, the above description should not be construed as limiting, but merely as exemplifications of aspects of the disclosure. Thus, the scope of the disclosure should be determined by the appended claims and their legal equivalents, rather than by the examples given.

What is claimed is:

1. An electronic control unit comprising:
a housing including a body and a cover, the body formed from a thermally conductive material and defining a cavity therein;
a first printed circuit board assembly and a second printed circuit board assembly, the first and second printed circuit board assemblies disposed within the cavity of the body; and
a passive thermal control system comprising:
a first thermal interface material positioned between the first printed circuit board assembly and the second printed circuit board assembly;
a second thermal interface material positioned between a heat-generating part of the second printed circuit board assembly and a first portion of an interior surface of the body; and
a third thermal interface material positioned between, and in contact with each of, the first printed circuit board assembly and a second different portion of the body,
the first thermal interface material, the second thermal interface material, and the heat-generating part being axially aligned with one another and each having a footprint that is substantially the same.

2. The electronic control unit according to claim 1, wherein the first printed circuit board assembly includes a printed circuit board having an interior array of vias defined therethrough, the interior array of vias being axially aligned with the first thermal interface material and having a footprint that is substantially the same as the first thermal interface material.

3. The electronic control unit according to claim 2, wherein a conductive trace is disposed over the interior array of vias and the first thermal interface material contacts the conductive trace.

4. The electronic control unit according to claim 1, wherein the body of the housing includes a shelf disposed within the cavity, and the second different portion of the body is part of the shelf, and wherein the first portion of the interior surface of the body is part of a wall of the body or some other part of the body that is different than the shelf.

5. The electronic control unit according to claim 4, wherein one or both of the shelf and the second different portion of the body extend(s) around an outer periphery of the cavity.

6. The electronic control unit according to claim 4, wherein the shelf is monolithically formed with at least a part of the body, the at least the part of the body including the first portion of the interior of the body.

7. The electronic control unit according to claim 4, wherein the third thermal interface material covers the shelf.

8. The electronic control unit according to claim 4, wherein the first printed circuit board assembly includes a printed circuit board having a peripheral array of vias defined therethrough and extending around a peripheral region of the printed circuit board, and the third thermal interface material is axially aligned with the peripheral array of vias.

9. The electronic control unit according to claim 8, wherein the peripheral array of vias has a footprint that is substantially the same as a footprint of the shelf.

10. The electronic control unit according to claim 8, wherein a conductive trace is disposed over the peripheral array of vias and the third thermal interface material contacts the conductive trace.

11. The electronic control unit according to claim 1, wherein the housing includes a plurality of mounting tabs extending from an outer surface of the body.

12. The electronic control unit according to claim 11, wherein the plurality of mounting tabs are longitudinally offset from a bottom wall of the body and an air gap is defined between the bottom wall and the plurality of mounting tabs.

13. The electronic control unit according to claim 12, wherein the bottom wall is textured.

14. The electronic control unit according to claim 1, wherein the cover is formed from a non-conductive material configured to allow passage of radio frequency energy therethrough.

15. The electronic control unit according to claim 14, further comprising an antenna disposed within the housing and electrically coupled to the first printed circuit board assembly or the second printed circuit board assembly, the antenna positioned adjacent the cover.

16. The electronic control unit according to claim 1, wherein the heat-generating part is a processor.

17. The electronic control unit according to claim 1, wherein the electronic control unit is cooled passively, without fans, in all modes of operation.

18. An electronic control unit system with modularity, the electronic control unit system with modularity to operate in a vehicle or other machine that includes a transportation system, in which the vehicle or other machine is suitable for transportation within, or operation within, a wide range of geographical areas, the electronic control unit with modularity including a modular heat transfer system, wherein the modular heat transfer system includes:
the passive thermal control system of the electronic control unit of claim 1, wherein heat is dissipated from protrusions external to the electronic control unit, or other features external to the electronic control unit; and
an active thermal control system releasably attachable to the electronic control unit, the active thermal control system thermally couplable to the passive thermal control system and configured to regulate a temperature within the electronic control unit when thermally coupled to the passive thermal control system;
wherein the modular heat removal system is operable:
without the active thermal control system attached thereto, in environmental conditions within a first threshold; and
with the active thermal control system operably coupled thereto, in environmental conditions with a second threshold, wherein the second threshold is different than the first threshold.

19. The electronic control unit system according to claim 18, wherein the active thermal control system includes a solid state thermoelectric device.

20. The electronic control unit of claim 18, wherein the transportation system comprises an off-highway transportation system.
